(19) United States
(12) Patent Application Publication
(10) Pub. No.: US 2025/0241030 A1
(43) Pub. Date: Jul. 24, 2025

(54) SEMICONDUCTOR DEVICE AND MANUFACTURING METHOD OF THE SEMICONDUCTOR DEVICE

(71) Applicant: SK hynix Inc., Icheon-si Gyeonggi-do (KR)

(72) Inventor: Jae Ho KIM, Icheon-si Gyeonggi-do (KR)

(73) Assignee: SK hynix Inc., Icheon-si Gyeonggi-do (KR)

(21) Appl. No.: 18/666,327

(22) Filed: May 16, 2024

(30) Foreign Application Priority Data
Jan. 24, 2024 (KR) 10-2024-0010723

(51) Int. Cl. H01L 29/06; H01L 29/423; H01L 29/66; H01L 29/775; H01L 29/786

(52) U.S. Cl. CPC H10D 62/121; H10D 30/014; H10D 30/43; H10D 30/6735; H10D 30/6757

(57) ABSTRACT

A semiconductor device according to an embodiment of the present disclosure includes a first channel sheet located over a lower structure and extending in a first direction, a gate layer covering a portion of the first channel sheet when coinciding with the first channel sheet in a second direction, the second direction being perpendicular to the first direction, and a gate insulating layer located between the first channel sheet and the gate layer, wherein the first channel sheet has a half-pipe structure including a curved surface in the second direction.

### CROSS-REFERENCE TO RELATED APPLICATION

The present application claims priority under 35 U.S.C. § 119 (a) to Korean patent application number 10-2024-0010723 filed on Jan. 24, 2024, in the Korean Intellectual Property Office, the entire disclosure of which application is incorporated by reference herein.

### BACKGROUND

### 1. Technical Field

Various embodiments of the present disclosure generally relate to a semiconductor device and a manufacturing method of the semiconductor device, and more particularly, to a semiconductor device including a transistor with a channel that has a sheet form.

### 2. Related Art

Field-effect transistors, such as finFET devices, have been developed to include a plurality of vertical fins that serve as conductive channel regions to enable larger effective conduction widths in small layout areas covering a substrate. However, due to the smaller width and area of circuits, the intervals between adjacent vertical pins may become too small to operate the vertical fins properly. Accordingly, gate-all-around (GAA) field effect transistors with improved performance, such as nanosheet transistors, are being developed.

### SUMMARY

According to an embodiment, a semiconductor device may include a first channel sheet located over a lower structure and extending in a first direction, a gate layer covering a portion of the first channel sheet when coinciding with the first channel sheet in a second direction, the second direction being perpendicular to the first direction, and a gate insulating layer located between the first channel sheet and the gate layer, wherein the first channel sheet has a half-pipe structure including a curved surface in the second direction.

According to an embodiment, a method of manufacturing a semiconductor device may include etching a portion of a lower structure such that an upper surface of the lower structure has a half-pipe structure extending in a first direction and curved in a second direction, the second direction being perpendicular to the first direction, forming a first channel sheet over the lower structure to have a similar curvature to the upper surface of the lower structure, forming a gate insulating layer that covers the first channel sheet, and forming a gate layer that covers a portion of the first channel sheet with the gate insulating layer interposed therebetween.

### BRIEF DESCRIPTION OF THE DRAWINGS

FIG. 1A is a perspective view illustrating a structure of a transistor included in a semiconductor device according to an embodiment of the present disclosure;

FIG. 1B is a diagram illustrating a cross-section of a transistor included in a semiconductor device according to an embodiment of the present disclosure;

FIGS. 2A to 2H are diagrams illustrating a method of manufacturing a transistor included in a semiconductor device according to an embodiment of the present disclosure; and

FIG. 3 is a diagram illustrating a cross-section of a transistor included in a semiconductor device according to another embodiment of the present disclosure.

### DETAILED DESCRIPTION

Specific structural or functional descriptions disclosed herein are merely illustrative for the purpose of describing embodiments according to the concept of the present disclosure. Embodiments according to the concept of the present disclosure may be implemented in various forms and should not be construed as being limited to the specific embodiments set forth herein. The terms “upper” and “lower” are merely for illustrative purposes, and based on different embodiments and different orientations of the same embodiment or different embodiments, the terms may vary.

Hereinafter, embodiments of the present disclosure will be described in detail with reference to the accompanying drawings in order for those skilled in the art to be able to readily implement the technical spirit of the present disclosure.

Various embodiments are directed to a semiconductor device capable of increasing a contact area between a channel sheet and a gate layer included in a transistor, and a method of manufacturing the semiconductor device.

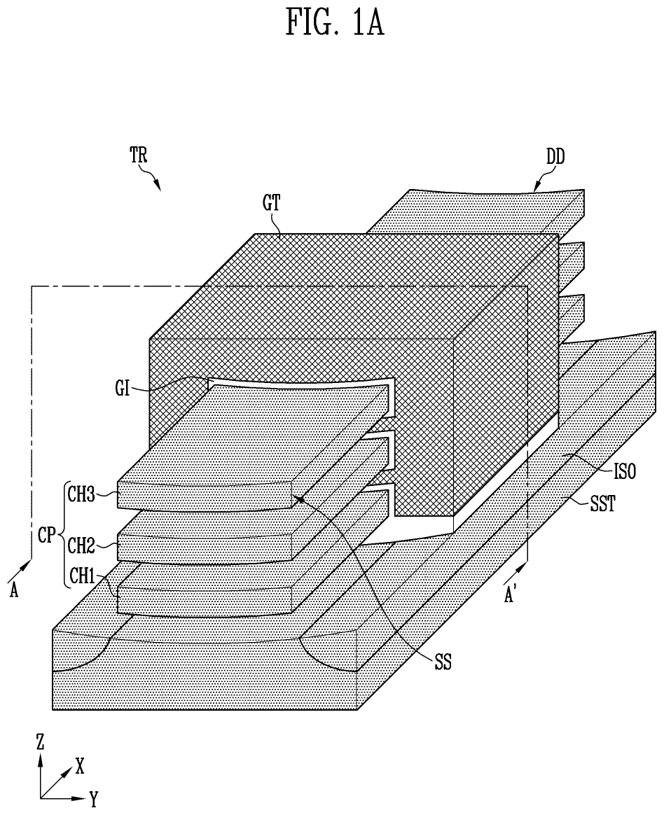

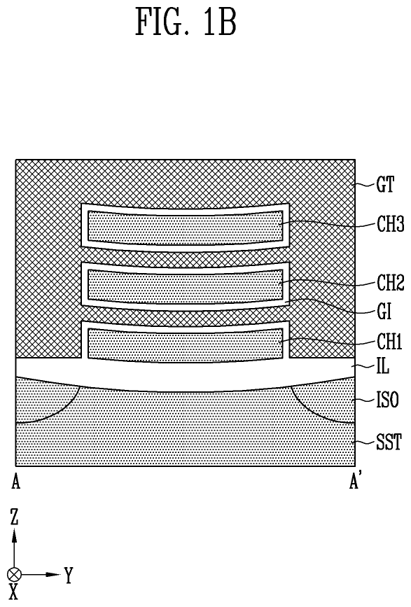

FIG. 1A is a perspective view illustrating a structure of a transistor included in a semiconductor device according to an embodiment of the present disclosure. FIG. 1B is a diagram illustrating a cross-section of the transistor included in the semiconductor device according to the embodiment of the present disclosure. FIG. 1B shows a cross-section taken along line A-A′ of FIG. 1A.

A lower structure SST may include a semiconductor substrate or a semiconductor layer. For example, the lower structure SST may include a single crystalline substrate, a silicon layer, Ge, SiC, GaAs, GaP, InP, InAs, InSb, SiGe, GaAsP, AlInAs, AlGaAs, GaInAs, GaInP, GaInAsP, or a combination thereof. In another example, the lower structure SST may include a semiconductor-on-insulator substrate, such as a silicon-on-insulator (SOI) substrate, a silicon germanium-on-insulator (SGOI) substrate, or a germanium-on-insulator substrate (GOI).

The lower structure SST may have an upper surface extending in an X direction and a Y direction and a lower surface. The upper surface of the lower structure SST may have a half-pipe structure that extends in the X direction and is curved in the Y direction. For example, the upper surface of the lower structure SST may be a curved surface that is concave in the Y direction and may extend linearly in the X direction, the curved surface being concave based on the upper surface of the lower structure SST being between the lower surface of the lower structure SST and the focus.

The lower structure SST may include an isolation layer ISO. The isolation layer ISO may include an insulating layer (e.g., a silicon oxide layer). An active region may be defined by the isolation layer ISO in the lower structure SST. A transistor TR may be located in the active region divided by the isolation layer ISO.

The transistor TR may include a channel pattern CP, a gate layer GT, gate insulating layers GI, a source SS, and a drain DD. The transistor TR may be formed over the lower structure SST. The transistor TR may have a channel in a gate-all-around (GAA) structure. For example, each of first to third channel sheets CH1 to CH3 included in the channel pattern CP may operate as a channel of the transistor TR.

The channel pattern CP may include channel sheets (e.g., the first channel sheet CH1, the second channel sheet CH2, and the third channel sheet CH3) that are stacked sequentially at predetermined intervals in the Z direction. Each of the first to third channel sheets CH1 to CH3 may be located over the lower structure SST. Each of the first to third channel sheets CH1 to CH3 may extend in the X direction. The number of channel sheets, the volume of each channel sheet, and the intervals between the channel sheets are not limited to those shown in FIGS. 1A and 1B and may vary based on the embodiment.

The first channel sheet CH1 may have a half-pipe structure so that the first channel sheet CH1 may have a curved surface in the Y direction. An upper surface and a lower surface of the first channel sheet CH1 may be single-curved surfaces. The first channel sheet CH1 may have a cross-section that is concave in the Y direction and may extend linearly in the X direction, the cross-section being concave based on the first channel sheet CH1 being between the upper surface of the lower structure SST and the focus. In other words, the upper and lower surfaces of a cross-section of the first channel sheet CH1 may form a flat surface in the X direction, while the upper and lower surfaces of a cross-section of the first channel sheet CH1 may form a curved surface in the Y direction.

The second and third channel sheets CH2 and CH3 may be sequentially arranged over the first channel sheet CH1 in the Z direction. Each of the second and third channel sheets CH2 and CH3 may have a half-pipe structure so that each of the second and third channel sheets CH2 and CH3 may have a curved surface in the Y direction. Each of the second and third channel sheets CH2 and CH3 may have the same structure as the first channel sheet CH1. For example, the first to third channel sheets CH1 to CH3 may have the same curvature.

The gate layer GT may extend in the X and Y directions over the lower structure SST. The gate layer GT may include a conductive material. The gate layer GT may cover a portion of each of the first to third channel sheets CH1 to CH3. For example, the gate layer GT may cover each of the first to third channel sheets CH1 to CH3 where the gate layer GT and the channel pattern CP coincide in the X direction. For example, the gate layer GT may be located between the first to third channel sheets CH1 to CH3, on both sides of each of the first to third channel sheets CH1 to CH3, and over the third channel sheet CH3.

The gate layer GT may cover the upper surface and both side surfaces of the first channel sheet CH1 in the Y direction. For example, referring to FIG. 1A, the gate layer GT may cover a portion of the upper surface and a portion of each of the side surfaces of the first channel sheet CH1 in the Y direction based on portions of the channel pattern CP not coinciding with the gate layer GT in the X direction.

The gate layer GT may cover an upper surface, a lower surface, and both side surfaces of the second channel sheet CH2 in the Y direction. For example, referring to FIG. 1A, the gate layer GT may cover a portion of the upper surface, a portion of the lower surface, and a portion of each of the side surfaces of the second channel sheet CH2 in the Y direction based on portions of the channel pattern CP not coinciding with the gate layer GT in the X direction.

The gate layer GT may cover an upper surface, a lower surface, and both side surfaces of the third channel sheet CH3 in the Y direction. For example, referring to FIG. 1A, the gate layer GT may cover a portion of the upper surface, a portion of the lower surface, and a portion of each of the side surfaces of the third channel sheet CH3 in the Y direction based on portions of the channel pattern CP not coinciding with the gate layer GT in the X direction.

Some regions of the channel pattern CP that are not covered by the gate layer GT may operate as the source SS or the drain DD. For example, a region that is located in an opposite direction to the X direction (−X direction) from the gate layer GT may be referred to as the source SS and a region that is located in the X direction (+X direction) from the gate layer GT may be referred to as the drain DD. However, the orientation of the transistor TR may vary, resulting in the source SS and drain DD being in opposite directions.

Referring to FIG. 1B, a gate insulating layer GI may be located between each of the first to third channel sheets CH1 to CH3 and the gate layer GT. The gate insulating layer GI may be interposed between each of the first to third channel sheets CH1 to CH3 and the gate layer GT. The gate insulating layer GI may contact the first to third channel sheets CH1 to CH3. In addition, the gate insulating layer GI may contact the gate layer GT. The first to third channel sheets CH1 to CH3 may be spaced apart based on the gate insulating layer GI to avoid direct contact between the first to third channel sheets CH1 to CH3.

Furthermore, an insulating layer IL may be located on the lower structure SST. The insulating layer IL may contact a curved upper surface of the lower structure SST and a lower curved surface of the first channel sheet CH1.

When a channel sheet (e.g., the first channel sheet CH1, the second channel sheet CH2, or the third channel sheet CH3) according to an embodiment of the present disclosure has a half-pipe structure, a contact area between the channel sheet (e.g., CH1, CH2, or CH3) and the gate layer GT may be greater than a channel sheet having a straight-line shape of a same length in the Y direction. In other words, assuming that the transistor TR occupies the same area on an X-Y plane, an area between the channel sheet and the gate layer GT adjacent to each other may increase when the channel sheet (e.g., CH1, CH2, or CH3) is bent as compared to when the channel sheet is not bent. Thus, according to an embodiment of the present disclosure, the occurrence of short channel effects may be prevented by improving the gate controllability of the transistor TR.

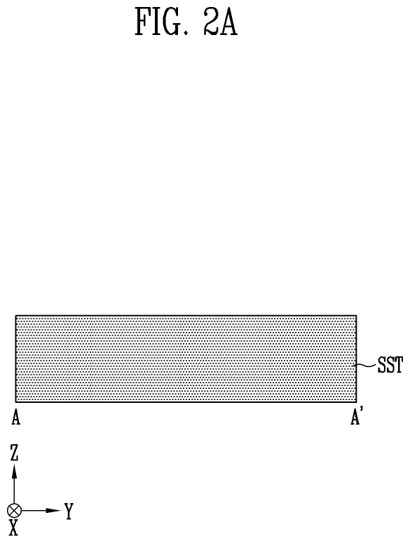

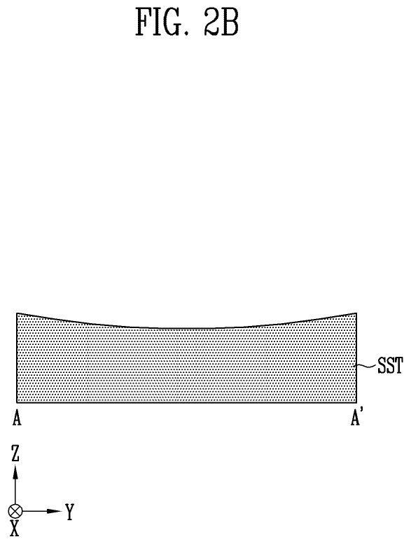

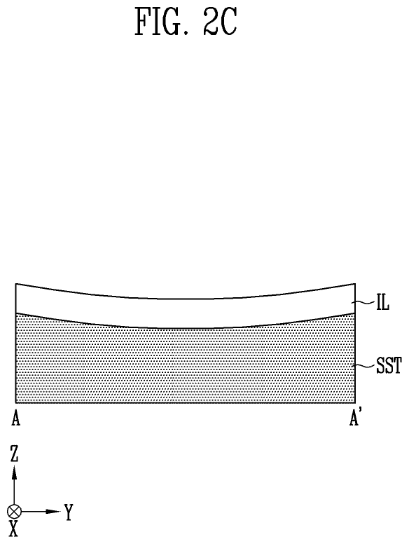

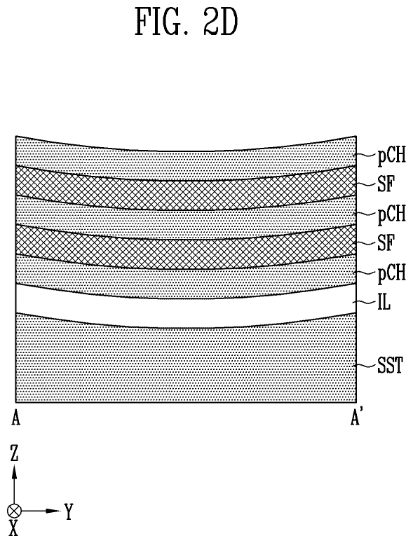

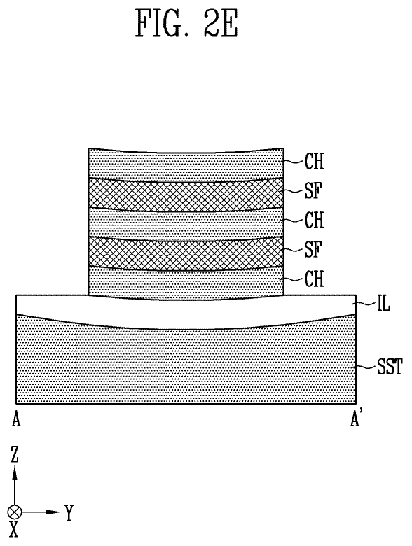

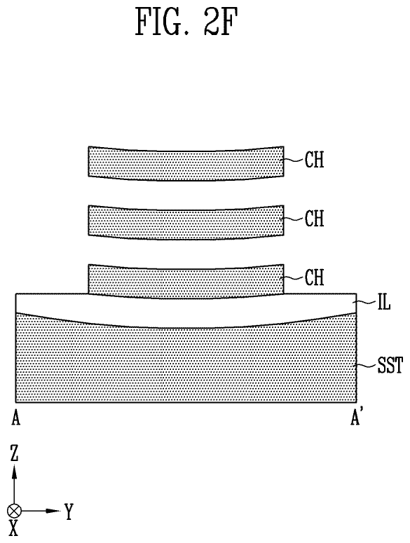

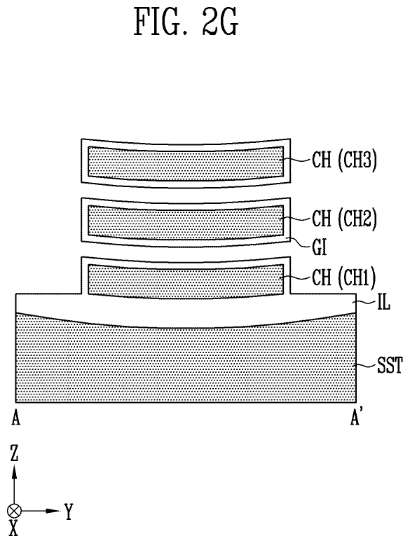

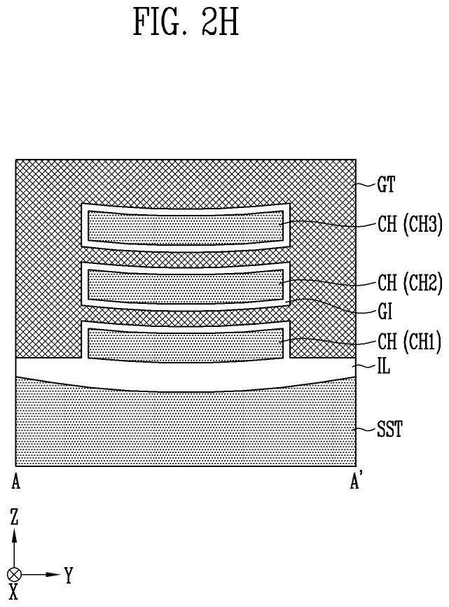

FIGS. 2A to 2H are diagrams illustrating a method of manufacturing a transistor included in a semiconductor device according to an embodiment of the present disclosure. FIGS. 2A to 2H show a cross-section taken along line A-A′ of FIG. 1A.

Referring to FIGS. 2A and 2B, a portion of the lower structure SST may be etched. An upper portion of the lower structure SST may be etched so that the upper surface of the lower structure SST may have a half-pipe structure that extends in the X direction and may be curved in the Y direction. For example, the portion of the lower structure SST may be etched so that the upper surface of the lower structure SST may have a structure that extends linearly in the X direction and curves in the Y direction. Though not shown, a process of forming the isolation layer ISO of FIG. 1A may be added before or after the etching of the lower structure SST.

Referring to FIG. 2C, an insulating layer IL may be formed on the lower structure SST. The insulating layer IL may contact a curved upper surface of the lower structure SST. The insulating layer IL may be conformally formed on the lower structure SST. Accordingly, the insulating layer IL may have a similar curvature to the curved surface of the lower structure SST. For example, the insulating layer IL may have a half-pipe structure that extends in the X direction and is curved in the Y direction. In addition, an upper surface and a lower surface of the insulating layer IL may have the same curvature as the upper surface of the lower structure SST. For example, the upper surface and the lower surface of the insulating layer IL may be single-curved surfaces. The insulating layer IL may have a cross-section that is concave in the Y direction and may extend linearly in the X direction, the cross-section being concave based on the insulating layer IL being between the lower structure SST and the focus. In other words, the upper and lower surfaces of a cross-section of the insulating layer IL may form a flat surface in the X direction, while the upper and lower surfaces of a cross-section of the insulating layer IL may form a curved surface in the Y direction. The insulating layer IL may include an oxide layer.

Referring to FIG. 2D, preliminary channel layers pCH and sacrificial layers SF may be alternately stacked over the lower structure SST. A lowermost preliminary channel layer pCH may contact the insulating layer IL. The preliminary channel layers pCH and the sacrificial layers SF may have similar curvatures to the curved surface of the insulating layer IL. In turn, the preliminary channel layers pCH and the sacrificial layers SF may have similar curvatures to the curved surface of the lower structure SST. For example, each of the preliminary channel layers pCH and the sacrificial layers SF may have a half-pipe structure that extends in the X direction and is curved in the Y direction. In addition, an upper surface and a lower surface of each of the preliminary channel layers pCH and the sacrificial layers SF may have the same curvature as the upper surface of the lower structure SST. For example, the upper surface and lower surfaces of each of the preliminary channel layers pCH and the sacrificial layers SF may be single-curved surfaces. Each of the preliminary channel layers pCH and the sacrificial layers SF may have a cross-section that is concave in the Y direction and may extend linearly in the X direction, the cross-section being concave based on the preliminary channel layers pCH being between the upper surface of the lower structure SST and the focus and the sacrificial layers SF being between the upper surface of the lower structure SST and the focus. In other words, the upper and lower surfaces of a cross-section of each of the preliminary channel layers pCH and the sacrificial layers SF may form a flat surface in the X direction, while the upper and lower surface of a cross-section of each of the preliminary channel layers pCH and the sacrificial layers SF may form a curved surface in the Y direction. The preliminary channel layers pCH may include silicon. The sacrificial layers SF may include silicon germanium.

Referring to FIG. 2E, a portion of each of the preliminary channel layers pCH and the sacrificial layers SF may be etched. For example, a hard mask (not shown) may be formed over an uppermost preliminary channel layer pCH to cover a portion of the preliminary channel layers pCH and may expose another portion. Both ends of each of the preliminary channel layers pCH and the sacrificial layers SF may be etched by using the hard mask. For example, an end in the Y direction (+Y direction) and an end in the opposite direction to the Y direction (−Y direction) of each of the preliminary channel layers pCH and the sacrificial layers SF may be etched. An anisotropic dry etching process may be performed to etch a predetermined area of each of the preliminary channel layers pCH and the sacrificial layers SF. When the preliminary channel layers pCH and the sacrificial layers SF are etched, a portion of the insulating layer IL may be etched.

Remaining portions, which are left after etching the portion of the preliminary channel layers pCH, may be referred to as channel sheets CH. As both ends of each of the preliminary channel layers pCH are etched, each of the channel sheets CH may have a sheet form that extends in the X direction. The channel sheets CH may be spaced apart from each other in the Z direction.

Each of the channel sheets CH may have a half-pipe structure so that each of the channel sheets CH may have a curved surface in the Y direction. The upper and lower surfaces of each of the channel sheets CH may be single-curved surfaces. Each of the channel sheets CH may have a cross-section that is concave in the Y direction and may extend linearly in the X direction, the cross-section being concave based on each of the channel sheet CH being between the upper surface of the lower structure SST and the focus. In other words, the upper and lower surfaces of a cross-section of each of the channel sheets CH may form a flat surface in the X direction, while the upper and lower surfaces of a cross-section of each of the channel sheets CH may form a curved surface in the Y direction.

Referring to FIG. 2F, the sacrificial layers SF may be removed. The sacrificial layers SF located between the channel sheets CH may be etched. The sacrificial layers SF may be etched by using an etchant for selectively etching the sacrificial layer SF. As the sacrificial layers SF are etched, an air gap may be formed between the channel sheets CH.

Referring to FIG. 2G, the gate insulating layers GI covering the channel sheets CH, respectively, may be formed. The gate insulating layers GI may be formed on surfaces of the channel sheets CH, respectively. For example, the gate insulating layer GI may contact the upper surface and both side surfaces of the first channel sheet CH1 in the Y direction. In addition, the gate insulating layer GI may contact the upper surface, the lower surface, and both side surfaces of each of the second and third channel sheets CH2 and CH3 in the Y direction.

The gate insulating layers GI contacting different channel sheets CH may be spaced apart from each other. For example, the gate insulating layer GI formed over the upper surface of the first channel sheet CH1 and the gate insulating layer GI formed over the lower surface of the second channel sheet CH2 may be spaced apart from each other.

The gate insulating layer GI may be formed through a method of oxidizing the channel sheets CH. Alternatively, the gate insulating layer GI may be formed by depositing an oxide layer on the channel sheets CH.

Referring to FIG. 2H, the gate layer GT covering the channel sheets CH may be formed. The gate layer GT may cover each of the channel sheets CH with the gate insulating layer GI interposed therebetween. The gate layer GT may be formed in gaps between the channel sheets CH, an upper portion of the channel sheets CH, and a lateral portion of each of the channel sheets CH. For example, the gate layer GT may be formed adjacent to the upper surface and both side surfaces of the first channel sheet CH1 in the Y direction. In addition, the gate layer GT may be formed adjacent to the upper surface, the lower surface, and both side surfaces of each of the second channel sheet CH2 and the third channel sheet CH3 in the Y direction. The gate layer GT may include a conductive material.

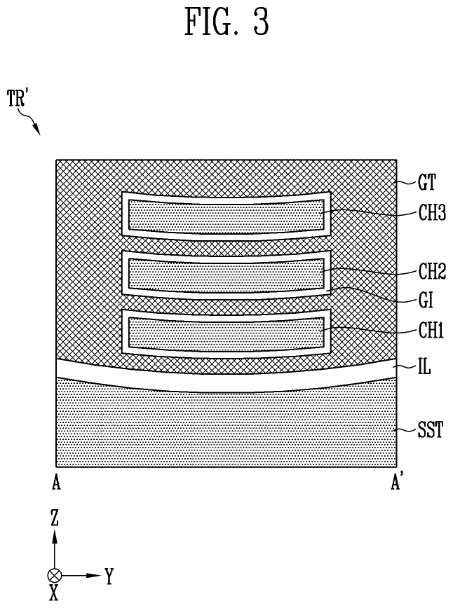

In FIG. 1A, FIG. 1B, and FIGS. 2A to 2H, it is described that the first channel sheet CH1 contacts the insulating layer IL, but embodiments of the present disclosure are not limited thereto. For example, the first channel sheet CH1 may be spaced apart from the insulating layer IL. In FIG. 3, an embodiment including the first channel sheet CH1 that is spaced apart from the insulating layer IL is shown.

FIG. 3 is a diagram illustrating a cross-section of a transistor included in a semiconductor device according to another embodiment of the present disclosure. In FIG. 3, descriptions of structures overlapping with those shown in FIG. 1A, FIG. 1B, and FIGS. 2A to 2H will be omitted or simplified.

Referring to FIG. 3, the gate layer GT may cover the upper surface, both side surfaces, and the lower surface of the first channel sheet CH1 in the Y direction. The first channel sheet CH1 may be spaced apart from the insulating layer IL in the Z direction. The gate insulating layer GI may be formed over the lower surface of the first channel sheet CH1. The gate layer GT may be formed adjacent to the lower surface of the first channel sheet CH1 with the gate insulating layer GI interposed therebetween.

A transistor TR′ may have a channel with a gate-all-around (GAA) structure. For example, each of the first to third channel sheets CH1 to CH3 that serve as a channel of the transistor TR′ may be covered by the gate layer GT in four directions.

According to embodiments of the present disclosure, increasing a contact area between a channel sheet and a gate layer included in a transistor may enhance gate controllability, thereby reducing an occurrence of short channel effects.

What is claimed is:

1. A semiconductor device, comprising:
a first channel sheet located over a lower structure and extending in a first direction;
a gate layer covering a portion of the first channel sheet when coinciding with the first channel sheet in a second direction, the second direction being perpendicular to the first direction; and
a gate insulating layer located between the first channel sheet and the gate layer;
wherein the first channel sheet has a half-pipe structure including a curved surface in the second direction.

2. The semiconductor device of claim 1, wherein an upper surface of the lower structure has a half-pipe structure extending in the first direction and curved in the second direction.

3. The semiconductor device of claim 1, further comprising a second channel sheet and a third channel sheet located over the first channel sheet and arranged in a third direction, the third direction being perpendicular to both the first direction and the second direction.

4. The semiconductor device of claim 3, wherein the second and third channel sheets have a same structure as the first channel sheet.

5. The semiconductor device of claim 3, wherein the gate layer covers a portion of the second channel sheet and a portion of the third channel sheet.

6. The semiconductor device of claim 3, wherein the gate layer covers a portion of an upper surface, a portion of a lower surface, and a portion of each side surface of each of the second and third channel sheets in the second direction.

7. The semiconductor device of claim 1, wherein the gate layer covers a portion of an upper surface and a portion of each side surface of the first channel sheet in the second direction.

8. The semiconductor device of claim 1, wherein the gate layer covers a portion of an upper surface, a portion of a lower surface, and a portion of each side surface of the first channel sheet in the second direction.

9. The semiconductor device of claim 1, wherein an upper surface and a lower surface of a cross section of the first channel sheet in the first direction form a flat surface, and
wherein an upper surface and a lower surface of a cross-section of the first channel sheet form a curved surface in the second direction.

10. The semiconductor device of claim 1, wherein the first channel sheet has a curved cross-section in the second direction, and
wherein the curved cross-section of the first channel sheet is concave based on the curved cross-section being between a focus and the lower structure.

11. A method of manufacturing a semiconductor device, the method comprising:
etching a portion of a lower structure such that an upper surface of the lower structure has a half-pipe structure extending in a first direction and curved in a second direction, the second direction being perpendicular to the first direction;
forming a first channel sheet over the lower structure to have a similar curvature to the upper surface of the lower structure;
forming a gate insulating layer that covers the first channel sheet; and
forming a gate layer that covers a portion of the first channel sheet with the gate insulating layer interposed therebetween.

12. The method of claim 11, wherein the etching of the portion of the lower structure further comprises etching the portion of the lower structure so that the upper surface of the lower structure extends linearly in the first direction and curves in the second direction, and
wherein the upper surface of the lower structure is concave in the second direction based on the upper surface of the lower structure being between a focus and a lower surface of the lower structure.

13. The method of claim 11, further comprising, before the forming of the first channel sheet, forming an insulating layer contacting the upper surface of the lower structure, wherein the insulating layer is formed to have a similar curvature to the upper surface of the lower structure.

14. The method of claim 11, wherein the forming of the first channel sheet is performed simultaneously with forming a second channel sheet and a third channel sheet that are located over the first channel sheet and arranged in a third direction, the third direction being perpendicular to both the first and second directions.

15. The method of claim 14, wherein the forming of the first to third channel sheets comprises:
alternately stacking preliminary channel layers and sacrificial layers over the lower structure; and
etching a portion of each of the preliminary channel layers and removing the sacrificial layers to form the first to third channel sheets.

16. The method of claim 14, wherein the forming of the gate layer comprises forming the gate insulating layer to cover the second to third channel sheets.

17. The method of claim 14, wherein the forming of the gate layer comprises forming the gate layer that covers a portion of an upper surface, a portion of a lower surface, and a portion of each side surface of each of the second and third channel sheets in the second direction.

18. The method of claim 11, wherein the forming the gate layer comprises forming the gate layer that covers a portion of an upper surface and a portion of each side surface of the first channel sheet in the second direction.

19. The method of claim 11, wherein the forming the gate layer comprises forming the gate layer that covers a portion of an upper surface, a portion of a lower surface, and a portion of each side surface of the first channel sheet in the second direction.
